(19) United States
(12) Patent Application Publication
(10) Pub. No.: US 2026/0271749 A1
(43) Pub. Date: Sep. 10, 2026

(54) SEMICONDUCTOR PACKAGE

(71) Applicant: Samsung Electronics Co., Ltd., Suwon-si (KR)

(72) Inventors: JEONGHWAN LEE, Hwaseong-si (KR); ILHO KIM, Yongin-si (KR)

(21) Appl. No.: 19/661,104

(22) Filed: Apr. 28, 2026

Related U.S. Application Data
(63) Continuation of application No. 17/862,469, filed on Jul. 12, 2022, now abandoned.

(30) Foreign Application Priority Data
Jul. 14, 2021 (KR) 10-2021-0092378

(51) Int. Cl. H10W 70/60; H10W 70/685; H10W 74/10; H10W 90/00; H10W 72/00; H10W 72/20

(52) U.S. Cl. CPC H10W 70/611; H10W 70/685; H10W 74/117; H10W 90/00; H10W 90/401; H10W 72/072; H10W 72/252; H10W 90/724

(57) ABSTRACT

A semiconductor package includes a package substrate, an interposer on the package substrate, a lower molding layer on the package substrate and surrounding the interposer, a first semiconductor chip on the lower molding layer, a chip connection terminal between the first semiconductor chip and the package substrate and surrounded by the lower molding layer, a second semiconductor chip on the lower molding layer and at an outer side of the first semiconductor chip, interposer connection terminals that connect the first and second semiconductor chips to the interposer, and an upper molding layer on the lower molding layer and surrounding the first and second semiconductor chips.

### CROSS-REFERENCE TO RELATED APPLICATION(S)

This application is a continuation application of U.S. Application No. 17/862,469, filed on July 12, 2022, which is based on and claims priority under 35 U.S.C. § 119 to Korean Patent Application No. 10-2021-0092378, filed on July 14, 2021, in the Korean Intellectual Property Office, the disclosure of which is incorporated by reference herein in its entirety.

### BACKGROUND

The present disclosure relates to semiconductor packages.

With recent advancements in semiconductor manufacturing techniques and the desire to provide more compact electronic devices, semiconductor packages including semiconductor chips are required to be thin and light while at the same time having increased storage capacity. There has been increased interest in providing semiconductor chips having various functions in a semiconductor package and quickly driving the semiconductor chips. There is therefore a need to provide improved semiconductor packages including a plurality of semiconductor chips that are thin and light, with the semiconductor chips electrically connected in an efficient manner, and methods of manufacturing the same.

### SUMMARY

Embodiments of the inventive concepts provide a thin and light semiconductor package having increased structural reliability with reduced manufacturing cost.

Embodiments of the inventive concepts provide a semiconductor package including a package substrate; an interposer on the package substrate; a lower molding layer on the package substrate and surrounding the interposer; a first semiconductor chip on the lower molding layer; a chip connection terminal between the first semiconductor chip and the package substrate, and surrounded by the lower molding layer, the chip connection terminal connecting the first semiconductor chip to the package substrate; a second semiconductor chip on the lower molding layer and at an outer side of the first semiconductor chip; interposer connection terminals configured to connect the first and second semiconductor chips to the interposer, the interposer connection terminals including a first interposer connection terminal between the first semiconductor chip and the interposer, and a second interposer connection terminal between the second semiconductor chip and the interposer; and an upper molding layer on the lower molding layer, and surrounding the first and second semiconductor chips.

Embodiments of the inventive concepts further provide a semiconductor package including a package substrate having a trench in an upper portion thereof; an interposer at least partially surrounded by inner surfaces of the package substrate, the inner surfaces of the package substrate defining the trench of the package substrate; a lower molding layer on the package substrate and surrounding the interposer; a first semiconductor chip on the lower molding layer; a chip connection terminal between the first semiconductor chip and the package substrate, and surrounded by the lower molding layer, the chip connection terminal connecting the first semiconductor chip to the package substrate; a second semiconductor chip on the lower molding layer and at an outer side of the first semiconductor chip; interposer connection terminals configured to connect the first and second semiconductor chips to the interposer, the interposer connection terminals including a first interposer connection terminal between the first semiconductor chip and the interposer, and a second interposer connection terminal between the second semiconductor chip and the interposer; an upper molding layer on the lower molding layer, and surrounding the first and second semiconductor chips; and a first adhesive layer between the interposer and the upper molding layer, and surrounding the interposer connection terminals.

Embodiments of the inventive concepts still further provide a semiconductor package including a package substrate; an interposer on the package substrate; a lower molding layer on the package substrate and surrounding the interposer; a first semiconductor chip on the lower molding layer; a chip connection terminal between the first semiconductor chip and the package substrate, and surrounded by the lower molding layer, the chip connection terminal connecting the first semiconductor chip to the package substrate; a semiconductor stack structure on the lower molding layer and at an outer side of the first semiconductor chip, the semiconductor stack structure including a plurality of semiconductor chips; interposer connection terminals connecting the first semiconductor chip and the semiconductor stack structure to the interposer, the interposer connection terminals including a first interposer connection terminal between the first semiconductor chip and the interposer, and a second interposer connection terminal between the semiconductor stack structure and the interposer; conductive pillars between the first semiconductor chip and the chip connection terminal, between the first semiconductor chip and the first interposer connection terminal, and between the semiconductor stack structure and the second interposer connection terminal; an upper molding layer on the lower molding layer, and surrounding the first semiconductor chip and the semiconductor stack structure; and a first adhesive layer between the interposer and the upper molding layer, and surrounding the interposer connection terminals.

According to embodiments of the inventive concepts, an interposer of a semiconductor package does not include a through silicon via that passes through at least a portion of an interposer substrate and directly connects a plurality of semiconductor chips to a package substrate. Accordingly, the semiconductor package including the interposer may be thin and light, and the manufacturing cost of the semiconductor package may be reduced.

According to further embodiments of the inventive concepts, a semiconductor package may include a package substrate having a trench accommodating at least a portion of an interposer. Accordingly, the semiconductor package may be thin and light.

According to further embodiments of the inventive concepts, an interposer of a semiconductor package may be firmly fixed to a package substrate by an adhesive layer and a molding layer. Accordingly, the structural stability of the semiconductor package may be increased.

According to still further embodiments of the inventive concepts, a method of manufacturing a semiconductor package may include connecting a plurality of semiconductor chips to each other through an interposer after fixing the semiconductor chips using an upper molding layer. Accordingly, the method does not include a step of aligning the semiconductor chips and the interposer. In addition, a resultant structure of each stage of the method may have structural stability, and accordingly the yield of the method may be increased.

### BRIEF DESCRIPTION OF THE DRAWINGS

Embodiments of the inventive concepts will be more clearly understood from the following detailed description taken in conjunction with the accompanying drawings in which:

FIG. 1 illustrates a cross-sectional view of a semiconductor package according to embodiments of the inventive concepts;

FIG. 2 illustrates an enlarged view of region A in FIG. 1;

FIG. 3 illustrates a cross-sectional view of a semiconductor package according to embodiments of the inventive concepts;

FIG. 4 illustrates a cross-sectional view of a semiconductor package according to embodiments of the inventive concepts;

FIG. 5 illustrates a cross-sectional view of a semiconductor package according to embodiments of the inventive concepts;

FIG. 6 illustrates a cross-sectional view of a semiconductor package according to embodiments of the inventive concepts;

FIG. 7 illustrates a cross-sectional view of a semiconductor package according to embodiments of the inventive concepts;

FIG. 8 illustrates a cross-sectional view of a semiconductor package according to embodiments of the inventive concepts;

FIG. 9 illustrates a cross-sectional view of a semiconductor package according to embodiments of the inventive concepts;

FIG. 10 illustrates a flowchart of a method of manufacturing a semiconductor package, according to embodiments of the inventive concepts; and

FIGS. 11, 12, 13, 14, 15, 16 and 17 illustrate diagrams of stages in a method of manufacturing a semiconductor package, according to embodiments of the inventive concepts.

### DETAILED DESCRIPTION

Hereinafter, preferred embodiments of the inventive concepts will be described with reference to the accompanying drawings. In the description that follows, like reference numerals will denote like elements, and redundant descriptions thereof will be omitted for conciseness. Throughout the description, relative locations of components may be described using terms such as “vertical”, “horizontal”, “over”, “higher”, “above” and so on. These terms are for descriptive purposes only, and are intended only to describe the relative locations of components assuming the orientation of the overall device is the same as that shown in the drawings. The embodiments however are not limited to the illustrated device orientations.

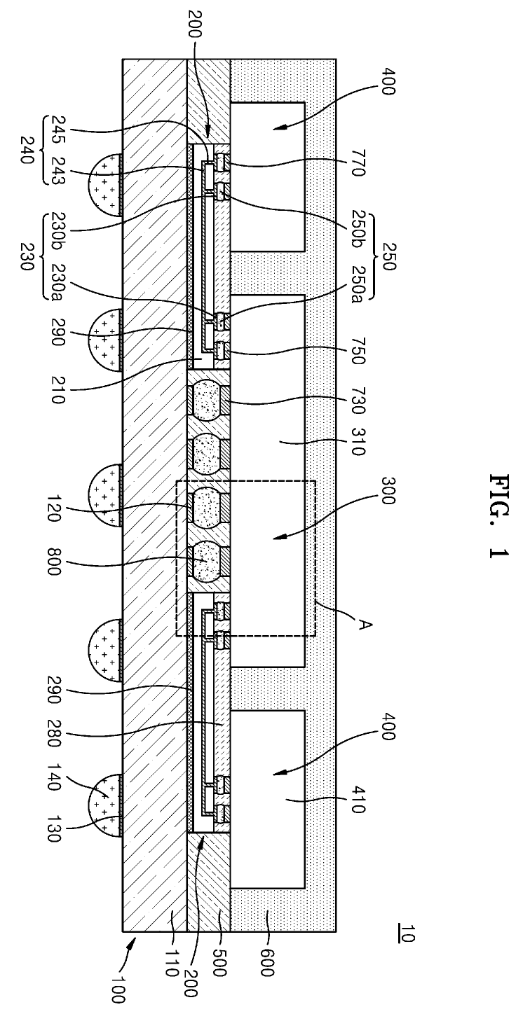

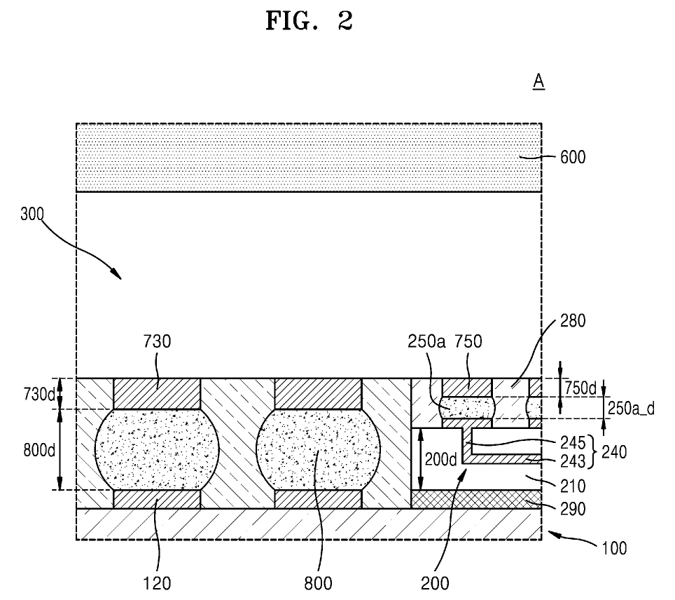

FIG. 1 illustrates a cross-sectional view of a semiconductor package 10 according to embodiments of the inventive concepts. FIG. 2 illustrates an enlarged view of region A in FIG. 1.

Referring to FIGS. 1 and 2, the semiconductor package 10 may include a package substrate 100, an interposer 200, a first adhesive layer 280, a second adhesive layer 290, a first semiconductor chip 300, a second semiconductor chip 400, a lower molding layer 500, an upper molding layer 600, first to third conductive pillars 730, 750, and 770, a chip connection terminal 800, and an interposer connection terminal 250.

The package substrate 100 of the semiconductor package 10 may include a base board layer 110, an upper package substrate pad 120 on the top surface of the base board layer 110, a lower package substrate pad 130 on the bottom surface of the base board layer 110, and a package connection terminal 140 attached to the lower package substrate pad 130.

In an example embodiment, the package substrate 100 may include a printed circuit board (PCB). For example, the package substrate 100 may include a multi-layer PCB.

The base board layer 110 may include at least one material selected from phenol resin, epoxy resin, and polyimide. For example, the base board layer 110 may include at least one material selected from frame retardant 4 (FR4), tetrafunctional epoxy, polyphenylene ether, epoxy/polyphenylene oxide, bismaleimide triazine (BT), thermount, cyanate ester, polyimide, and liquid crystal polymer.

The upper package substrate pad 120 may be on the top surface of the base board layer 110 and in contact with the chip connection terminal 800 on the first semiconductor chip 300. In an example embodiment, the upper package substrate pad 120 may be in a central portion of the package substrate 100 along a vertical direction.

The lower package substrate pad 130 may be on the bottom surface of the base board layer 110 and in contact with the package connection terminal 140.

In an example embodiment, the upper package substrate pad 120 and the lower package substrate pad 130 may include at least one material selected from copper, nickel, stainless steel, and beryllium copper for example.

The package substrate 100 may include a substrate wiring pattern (not shown), which extends inside the base board layer 110 and is configured to connect the upper package substrate pad 120 to the lower package substrate pad 130. The substrate wiring pattern may include a substrate wiring line pattern (not shown) which extends in the base board layer 110 in a horizontal direction, and a substrate wiring via pattern (not shown) which extends in the base board layer 110 in a vertical direction.

Hereinafter, the horizontal direction may be defined as being parallel with a direction in which the top and bottom surfaces of the package substrate 100 extend, and the vertical direction may be defined as being perpendicular to the direction in which the top and bottom surfaces of the package substrate 100 extend.

In an example embodiment, the substrate wiring pattern may include at least one material selected from electrolytically deposited (ED) copper, rolled-annealed (RA) copper foil, stainless steel foil, aluminum foil, ultra-thin copper foil, sputtered copper, copper alloys, nickel, stainless steel, and beryllium copper for example.

The base board layer 110 may further include a solder resist layer (not shown) on each of the top and bottom surfaces thereof to expose either the upper package substrate pad 120 or the lower package substrate pad 130. The solder resist layer may include at least one material selected from a polyimide film, a polyester film, a flexible solder mask, a photo-imageable coverlay (PIC), and photo-imageable solder resist for example.

The package connection terminal 140 may be attached to a surface of the lower package substrate pad 130 and electrically connect the semiconductor package 10 to an external device. The package connection terminal 140 may include a solder ball including at least one material selected from copper (Cu), aluminum (Al), silver (Ag), tin, and gold (Au) for example.

The interposer 200 of the semiconductor package 10 may be mounted on the package substrate 100. The interposer 200 may be configured to electrically connect the first semiconductor chip 300 and the second semiconductor chip 400, which are above the interposer 200, to each other.

In an example embodiment, there may be a plurality of interposers 200. As shown in FIG. 1, each of the interposers 200 may be configured to electrically connect the first semiconductor chip 300 to the second semiconductor chip 400. However, other embodiments are not limited to the descriptions given above, and at least one of the interposers 200 may be configured to electrically connect a plurality of second semiconductor chips 400 to each other.

In an example embodiment, each of the interposers 200 may be arranged on the package substrate 100 to overlap at least a portion of the first semiconductor chip 300 and at least a portion of the second semiconductor chip 400 in the vertical direction. For example, a side surface of an interposer 200, which side surface is closest to the central portion of the package substrate 100 from among the side surfaces of the interposer 200, may overlap a portion of the first semiconductor chip 300 in the vertical direction. Another side surface of the interposer 200, which side surface is closest to an edge of the package substrate 100 from among the side surfaces of the interposer 200, may overlap a portion of the second semiconductor chip 400 in the vertical direction.

A plurality of interposers 200 may be arranged at an outer side of the chip connection terminal 800. For example, according to a top view of the semiconductor package 10, the interposers 200 may surround the side portion of the chip connection terminal 800.

In an example embodiment, according to a top view of the semiconductor package 10, the horizontal cross-sectional area of an interposer 200 may be less than the horizontal cross-sectional area of the package substrate 100. The horizontal length of the interposer 200 may be less than the horizontal length of the package substrate 100.

In example embodiments, the interposer 200 does not include a through silicon via which passes through at least a portion of an interposer substrate 210 and directly connects the first and second semiconductor chips 300 and 400 to the package substrate 100. Accordingly, the interposer 200 may be thinner and lighter than an interposer including a through silicon via.

In an example embodiment, the vertical length (i.e., thickness) of the interposer 200 may be about 20 micrometers to about 200 micrometers. For example, a vertical length 200d of the interposer 200 may be less than a vertical length of each of the first and second semiconductor chips 300 and 400.

The interposer 200 may include the interposer substrate 210, an interposer upper pad 230, and an interposer wiring pattern 240. The interposer substrate 210 of the interposer 200 may include a semiconductor material, glass, ceramic, or plastic. For example, the interposer substrate 210 may include silicon. However, embodiments are not limited to those described above, and the interposer substrate 210 may include at least one material selected from an oxide, a nitride, and photo-imageable dielectric (PID). For example, the interposer substrate 210 may include silicon oxide, silicon nitride, epoxy, or polyimide.

The interposer upper pad 230 of the interposer 200 may be on the top surface of the interposer substrate 210 and configured to electrically connect the first and second semiconductor chips 300 and 400 to the interposer wiring pattern 240.

In an example embodiment, the interposer upper pad 230 may include a first interposer upper pad 230a which is configured to electrically connect the first semiconductor chip 300 to the interposer wiring pattern 240, and a second interposer upper pad 230b which is configured to electrically connect the second semiconductor chip 400 to the interposer wiring pattern 240.

In an example embodiment, the first interposer upper pad 230a may be arranged on the interposer substrate 210 to overlap at least a portion of the first semiconductor chip 300 in the vertical direction, and the second interposer upper pad 230b may be arranged on the interposer substrate 210 to overlap at least a portion of the second semiconductor chip 400 in the vertical direction. Because the first semiconductor chip 300 is in the central portion of the semiconductor package 10 and a plurality of second semiconductor chips 400 are respectively at outer sides of the first semiconductor chip 300, the first interposer upper pad 230a may be closer to the central portion of the package substrate 100 than the second interposer upper pad 230b.

In an example embodiment, the interposer upper pad 230 may include at least one material selected from Cu, nickel (Ni), stainless steel, and beryllium copper.

The interposer wiring pattern 240 of the interposer 200 may extend inside the interposer substrate 210 and electrically connect the first interposer upper pad 230a to the second interposer upper pad 230b. In other words, the interposer wiring pattern 240 may be connected to the first and second interposer upper pads 230a and 230b and may thus electrically connect the first semiconductor chip 300 to the second semiconductor chip 400.

In an example embodiment, the interposer wiring pattern 240 may include an interposer line pattern 243 which extends inside the interposer substrate 210 in the horizontal direction. The interposer wiring pattern 240 may also include an interposer via pattern 245 which extends inside the interposer substrate 210 in the vertical direction and is configured to connect the interposer line pattern 243 to the first interposer upper pad 230a or the second interposer upper pad 230b.

In an example embodiment, the material of the interposer wiring pattern 240 may include Cu. However, embodiments are not limited thereto. The interposer wiring pattern 240 may include metal such as for example Ni, Au, Ag, Al, tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), or ruthenium (Ru), or an alloy thereof.

The interposer connection terminal 250 may be between the first semiconductor chip 300 and the interposer 200, and between the second semiconductor chip 400 and the interposer 200, and may be configured to electrically connect the first and second semiconductor chips 300 and 400 to the interposer wiring pattern 240.

In detail, the interposer connection terminal 250 may include a first interposer connection terminal 250a between a second conductive pillar 750 on the first semiconductor chip 300 and the first interposer upper pad 230a, and a second interposer connection terminal 250b between a third conductive pillar 770 on the second semiconductor chip 400 and the second interposer upper pad 230b.

In an example embodiment, the interposer connection terminal 250 may include at least one material selected from Cu, Al, Ag, Sn, and Au.

In an example embodiment, a vertical length 250a-d of the first interposer connection terminal 250a and a vertical length of the second interposer connection terminal 250b may be about 10 micrometers to about 100 micrometers.

In an example embodiment, the first adhesive layer 280 may be on the interposer 200. In detail, the first adhesive layer 280 may be arranged between a portion of the top surface of the interposer 200 and a portion of the bottom surface of the first semiconductor chip 300, between a portion of the top surface of the interposer 200 and a portion of the bottom surface of the second semiconductor chip 400, and between a portion of the top surface of the interposer 200 and a portion of the bottom surface of the upper molding layer 600. The first adhesive layer 280 may be configured to fix the interposer 200 to the bottom of the first semiconductor chip 300, the bottom of the second semiconductor chip 400, and the bottom of the upper molding layer 600.

In an example embodiment, the first adhesive layer 280 may include a non-conductive film (NCF), non-conductive paste (NCP), an insulating polymer, or epoxy resin.

In an example embodiment, the first adhesive layer 280 may be arranged on the interposer 200 to surround the interposer connection terminal 250, the second conductive pillar 750 on the first semiconductor chip 300, and the third conductive pillar 770 on the second semiconductor chip 400.

In an example embodiment, the second adhesive layer 290 may be below the interposer 200. In detail, the second adhesive layer 290 may be between the bottom surface of the interposer 200 and the top surface of the package substrate 100. The second adhesive layer 290 may be configured to fix the interposer 200 to the package substrate 100. However, embodiments are not limited to the descriptions above. The second adhesive layer 290 may be omitted from the semiconductor package 10.

In an example embodiment, the second adhesive layer 290 may include an NCF, NCP, an insulating polymer, or epoxy resin.

In an example embodiment, a side surface of the first adhesive layer 280 and a side surface of the second adhesive layer 290 may be coplanar with a side surface of the interposer substrate 210.

The lower molding layer 500 may be arranged on the package substrate 100 to surround the interposer 200, the first adhesive layer 280, the second adhesive layer 290, the chip connection terminal 800, and so on. In detail, the lower molding layer 500 in the central portion of the package substrate 100 may surround the side of the chip connection terminal 800, and the lower molding layer 500 in the edge portion of the package substrate 100 may surround the sides of the interposer 200, the first adhesive layer 280, and the second adhesive layer 290.

In an example embodiment, the top surface of the lower molding layer 500 may be coplanar with the bottom surface of the first semiconductor chip 300, the bottom surface of the second semiconductor chip 400, and the bottom surface of the upper molding layer 600. The top surface of the lower molding layer 500 may be coplanar with the top surface of the first adhesive layer 280.

The first semiconductor chip 300 may be on the lower molding layer 500. In an example embodiment, the first semiconductor chip 300 may be in the central portion of the lower molding layer 500. The first semiconductor chip 300 may be mounted on the lower molding layer 500 such that the edge portion of the first semiconductor chip 300 overlaps at least a portion of each of a plurality of interposers 200 in the vertical direction.

In an example embodiment, the first semiconductor chip 300 may include a logic semiconductor chip. The logic semiconductor chip may include, for example, a central processor unit (CPU), a microprocessor unit (MPU), a graphics processor unit (GPU), or an application processor (AP).

The first semiconductor chip 300 may include a first semiconductor substrate 310 having an active layer (not shown). In an example embodiment, the first semiconductor substrate 310 may include silicon (Si). The first semiconductor substrate 310 may include a semiconductor element, e.g., germanium (Ge), or a compound semiconductor such as silicon carbide (SiC), gallium arsenide (GaAs), indium arsenide (InAs), or indium phosphide (InP).

In an example embodiment, the first semiconductor substrate 310 may have the active layer in a portion (e.g., the lower portion of the first semiconductor substrate 310) adjacent to the interposer 200. The active layer may include various kinds of individual devices. For example, the individual devices may include various microelectronic devices, e.g., a complementary metal-oxide-semiconductor (CMOS) transistor, a metal-oxide-semiconductor field effect transistor (MOSFET), a system large scale integration (LSI), an image sensor such as a CMOS image sensor (CIS), a micro-electro-mechanical system (MEMS), an active element, and a passive element.

The second semiconductor chip 400 may be on the lower molding layer 500 and at an outer side of the first semiconductor chip 300. For example, the second semiconductor chip 400 may be in the edge portion of the lower molding layer 500.

In an example embodiment, there may be a plurality of second semiconductor chips 400. The second semiconductor chips 400 may be further outside than a side surface of the first semiconductor chip 300 to surround at least a portion of the first semiconductor chip 300.

For example, there may be six second semiconductor chips 400. According to the top view of the semiconductor package 10, four second semiconductor chips 400 may for example be respectively mounted on the corners of the lower molding layer 500, and each of the remaining two second semiconductor chips 400 may be between two adjacent corners of the lower molding layer 500.

However, embodiments are not limited thereto, and there may be four second semiconductor chips 400. According to the top view of the semiconductor package 10, four second semiconductor chips 400 may for example be respectively mounted on the corners of the lower molding layer 500 to surround the first semiconductor chip 300.

A second semiconductor chip 400 may include a memory semiconductor chip. For example, the memory semiconductor chip may include a volatile memory semiconductor chip such as dynamic random access memory (DRAM) or static RAM (SRAM), or a non-volatile memory semiconductor chip such as phase-change RAM (PRAM), magneto-resistive RAM (MRAM), ferroelectric RAM (FeRAM), or resistive RAM (RRAM).

The second semiconductor chip 400 may include a second semiconductor substrate 410 having an active layer. Descriptions about the second semiconductor chip 400 that are redundant to description of the first semiconductor chip 300 are omitted for conciseness.

The semiconductor package 10 may include a system-in-package (SiP), in which different types of semiconductor chips (e.g., the first and second semiconductor chips 300 and 400) are electrically connected to each other and operate as a single system.

In an example embodiment, the vertical length (i.e., thickness) of the first semiconductor chip 300 may be substantially the same as the vertical length of the second semiconductor chip 400. In other words, the thickness of the first semiconductor chip 300 may be substantially the same as the thickness of the second semiconductor chip 400, and the top surface of the first semiconductor chip 300 may be coplanar with the top surface of the second semiconductor chip 400. However, embodiments are not limited to the descriptions above. The vertical length of the first semiconductor chip 300 may be different from the vertical length of the second semiconductor chip 400.

The first conductive pillar 730 may be on the bottom surface of the first semiconductor chip 300. The first conductive pillar 730 may be electrically connected to individual devices in the active layer of the first semiconductor chip 300. For example, the first conductive pillar 730 may be in the central portion of the bottom surface of the first semiconductor chip 300 and electrically connected to individual devices in the active layer of the first semiconductor chip 300.

In an example embodiment, the top surface of the first conductive pillar 730 may be in contact with the bottom surface of the first semiconductor chip 300, and the bottom surface of the first conductive pillar 730 may be in contact with the chip connection terminal 800. The side of the first conductive pillar 730 may be surrounded by the lower molding layer 500.

In an example embodiment, a vertical length 730d of the first conductive pillar 730 may be about 10 micrommeters to about 150 micrometers. The vertical length 730d of the first conductive pillar 730 may be greater than a vertical length 750d of the second conductive pillar 750 and the vertical length of the third conductive pillar 770.

In an example embodiment, the material of the first conductive pillar 730 may include at least one selected from Cu, Sn, Ag, and Al. For example, the material of the first conductive pillar 730 may include Cu.

The second conductive pillar 750 may be arranged on the bottom surface of the first semiconductor chip 300 to be at an outer side of the first conductive pillar 730. The second conductive pillar 750 may be electrically connected to individual devices in the active layer of the first semiconductor chip 300. For example, the second conductive pillar 750 may be in the edge portion of the bottom surface of the first semiconductor chip 300 and electrically connected to individual devices in the active layer of the first semiconductor chip 300.

In an example embodiment, the top surface of the second conductive pillar 750 may be in contact with the bottom surface of the first semiconductor chip 300, and the bottom surface of the second conductive pillar 750 may be in contact with the first interposer connection terminal 250a. The side of the second conductive pillar 750 may be surrounded by the first adhesive layer 280.

In an example embodiment, the vertical length 750d of the second conductive pillar 750 may be about 10 micrometers to about 150 micrometers. The vertical length 750d of the second conductive pillar 750 may be less than the vertical length 730d of the first conductive pillar 730. For example, the vertical length 750d of the second conductive pillar 750 may be about 10 micrometers to about 150 micrometers and less than the vertical length 730d of the first conductive pillar 730.

Accordingly, the bottom surface of the second conductive pillar 750 may be at a higher level than the bottom surface of the first conductive pillar 730. In other words, the vertical distance between the bottom surface of the second conductive pillar 750 and the top surface of the package substrate 100 may be greater than the vertical distance between the bottom surface of the first conductive pillar 730 and the top surface of the package substrate 100.

In an example embodiment, the material of the second conductive pillar 750 may be substantially the same as the material of the first conductive pillar 730. For example, the material of the second conductive pillar 750 may include Cu. However, embodiments are not limited to the descriptions above. The material of the second conductive pillar 750 may be different from the material of the first conductive pillar 730.

The third conductive pillar 770 may be on the bottom surface of the second semiconductor chip 400. The third conductive pillar 770 may be below the second semiconductor chip 400 and electrically connected to individual devices in the active layer of the second semiconductor chip 400.

In an example embodiment, the top surface of the third conductive pillar 770 may be in contact with the bottom surface of the second semiconductor chip 400, and the bottom surface of the third conductive pillar 770 may be in contact with the second interposer connection terminal 250b. The side of the third conductive pillar 770 may be surrounded by the first adhesive layer 280.

In an example embodiment, the vertical length of the third conductive pillar 770 may be about 10 micrometers to about 150 micrometers. The vertical length of the third conductive pillar 770 may be less than the vertical length 730d of the first conductive pillar 730 and substantially equal to the vertical length 750d of the second conductive pillar 750. For example, the vertical length of the third conductive pillar 770 may be about 10 micrometers to about 150 micrometers and less than the vertical length 730d of the first conductive pillar 730, and substantially equal to the vertical length 750d of the second conductive pillar 750.

Accordingly, the bottom surface of the third conductive pillar 770 may be at a higher level than the bottom surface of the first conductive pillar 730. The bottom surface of the third conductive pillar 770 may be at the same level as the bottom surface of the second conductive pillar 750.

The vertical distance between the bottom surface of the third conductive pillar 770 and the top surface of the package substrate 100 may be greater than the vertical distance between the bottom surface of the first conductive pillar 730 and the top surface of the package substrate 100. The vertical distance between the bottom surface of the third conductive pillar 770 and the top surface of the package substrate 100 may be substantially the same as the vertical distance between the bottom surface of the second conductive pillar 750 and the top surface of the package substrate 100.

However, embodiments are not limited to the descriptions above. The first to third conductive pillars 730, 750, and 770 may have substantially the same vertical length.

In an example embodiment, the material of the third conductive pillar 770 may be substantially the same as the material of the first and second conductive pillars 730 and 750. For example, the material of the third conductive pillar 770 may include Cu.

The chip connection terminal 800 may be between the first semiconductor chip 300 and the second semiconductor chip 400, and may electrically connect individual devices of the first semiconductor chip 300 to the package substrate 100.

In detail, the chip connection terminal 800 may be between the first conductive pillar 730 and the upper package substrate pad 120. The chip connection terminal 800 may be surrounded by the lower molding layer 500.

In an example embodiment, the chip connection terminal 800 may overlap a central portion of the first semiconductor chip 300 in the vertical direction. The chip connection terminal 800 may be between a plurality of interposers 200.

In an example embodiment, a vertical length 800d of the chip connection terminal 800 may be greater than the vertical length of each of the first and second interposer connection terminals 250a and 250b. For example, the vertical length 800d of the chip connection terminal 800 may be about 30 micrometers to about 300 micrometers. The vertical length 800d of the chip connection terminal 800 may be greater than the vertical length 200d of the interposer 200.

In an example embodiment, the chip connection terminal 800 may include a solder ball including at least one material selected from Cu, Al, Ag, Sn, and Au.

According to an example embodiment, the interposer 200 of the semiconductor package 10 does not include a through silicon via which passes through at least a portion of the interposer substrate 210 and directly connects a plurality of semiconductor chips, e.g., the first and second semiconductor chips 300 and 400, to the package substrate 100. Accordingly, the semiconductor package 10 including the interposer 200 may be thin and light, and the manufacturing cost of the semiconductor package 10 may be reduced.

In addition, the semiconductor package 10 may include the interposer 200, which is between each of a plurality of semiconductor chips, e.g., the first and second semiconductor chips 300 and 400, and the package substrate 100, and which is supported by the package substrate 100. Accordingly, the structural reliability of the semiconductor package 10 may be increased.

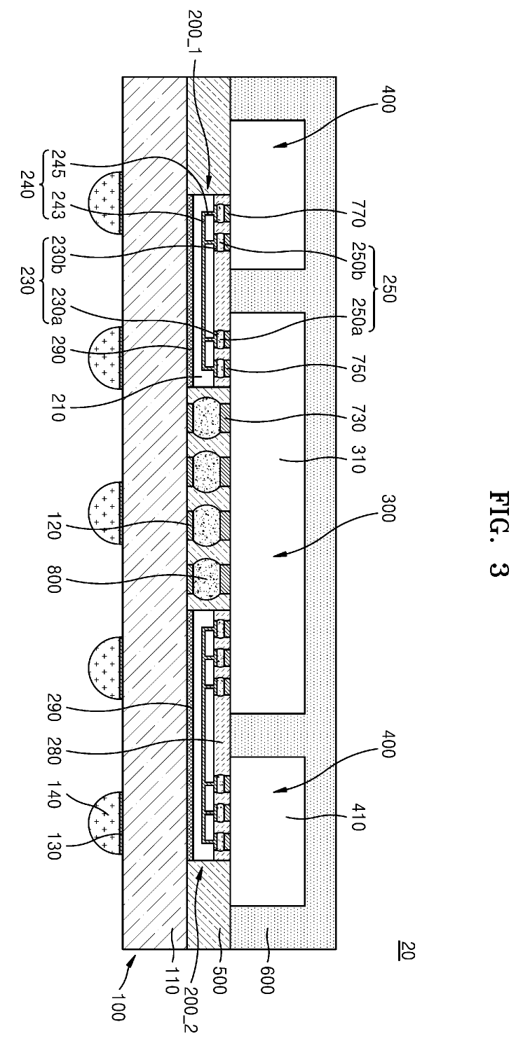

FIG. 3 illustrates a cross-sectional view of a semiconductor package 20 according to embodiments of the inventive concepts.

Hereinafter, description of the semiconductor package 20 of FIG. 3 that is redundant with the description of the semiconductor package 10 of FIGS. 1 and 2 is omitted for conciseness, and description hereinafter will be focused on differences between the semiconductor packages 10 and 20.

In an example embodiment, the semiconductor package 20 may include a first interposer 200_1 and a second interposer 200_2. In an example embodiment, each of the first interposer 200_1 and the second interposer 200_2 may include the interposer substrate 210, the interposer upper pad 230, and the interposer wiring pattern 240.

In an example embodiment, the size of the first interposer 200_1 may be different from the size of the second interposer 200_2. For example, the horizontal length of the first interposer 200_1 may be less than the horizontal length of the second interposer 200_2. The vertical length (i.e., thickness) of the first interposer 200_1 may be substantially equal to the vertical length (i.e., thickness) of the second interposer 200_2.

In an example embodiment, according to the top view of the semiconductor package 20, the cross-sectional area of the first interposer 200_1 may be less than the cross-sectional area of the second interposer 200_2. According to the top view of the semiconductor package 20, the cross-sectional area of a portion of the first interposer 200_1, which overlaps the first semiconductor chip 300 in the vertical direction, may be less than the cross-sectional area of a portion of the second interposer 200_2, which overlaps the first semiconductor chip 300 in the vertical direction.

In an example embodiment, because the cross-sectional area of the second interposer 200_2 is greater than the cross-sectional area of the first interposer 200_1, the number of interposer upper pads 230 of the second interposer 200_2 may be greater than the number of interposer upper pads 230 of the first interposer 200_1.

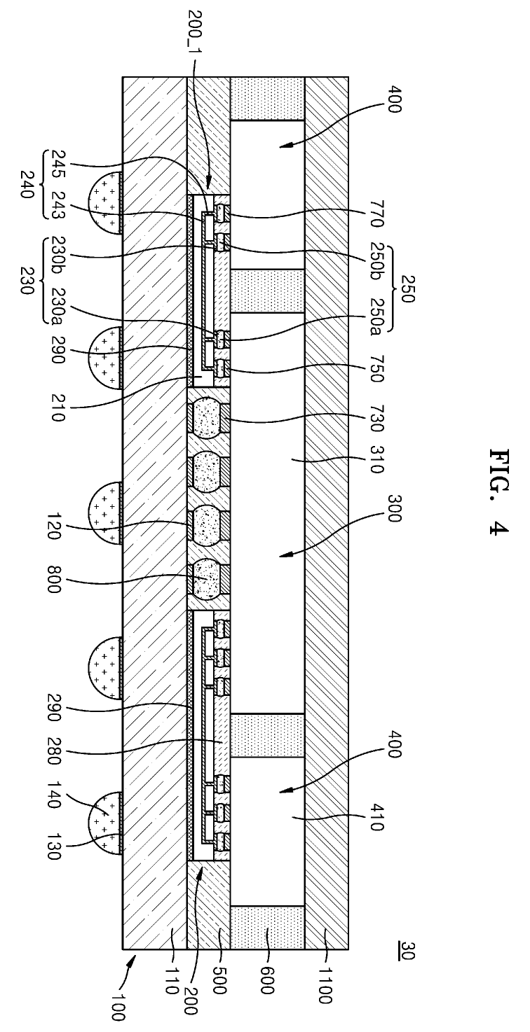

FIG. 4 illustrates a cross-sectional view of a semiconductor package 30 according to embodiments of the inventive concepts.

Hereinafter, description of the semiconductor package 30 of FIG. 4 that is redundant with the description of the semiconductor package 20 of FIG. 3 is omitted for conciseness, and description hereinafter will be focused on differences between the semiconductor packages 20 and 30.

According to an example embodiment, the semiconductor package 30 may further include a heat dissipation unit 1100 (i.e., a heat dissipater).

The heat dissipation unit 1100 of the semiconductor package 30 may be on the first semiconductor chip 300, the second semiconductor chip 400, and the upper molding layer 600. The heat dissipation unit 1100 may be configured to emit heat, which is generated by the first and second semiconductor chips 300 and 400, to the outside.

In an example embodiment, the heat dissipation unit 1100 may include a heat sink. However, embodiments are not limited to the descriptions above. The heat dissipation unit 1100 may include at least one selected from a heat spreader, a heat pipe, and a liquid cooled cold plate.

In an example embodiment, the top surface of the upper molding layer 600 may be coplanar with the top surface of the first semiconductor chip 300 and the top surface of the second semiconductor chip 400. Accordingly, the heat dissipation unit 1100 may be in contact with the top surface of the first semiconductor chip 300, the top surface of the second semiconductor chip 400, and the top surface of the upper molding layer 600. For example, the bottom surface of the heat dissipation unit 1100 may be coplanar with the top surface of the first semiconductor chip 300, the top surface of the second semiconductor chip 400, and the top surface of the upper molding layer 600.

In an example embodiment, the heat dissipation unit 1100 may include at least one selected from a metallic material, a ceramic material, a carbon-based material, and a polymeric material. For example, the heat dissipation unit 1100 may include a metallic material such as Al, Mg, Cu, Ni, and Ag.

According to an example embodiment, because the top surface of the upper molding layer 600 of the semiconductor package 30 may be coplanar with the top surface of the first semiconductor chip 300 and the top surface of the second semiconductor chip 400, the semiconductor package 30 may be thin and light.

In addition, because the heat dissipation unit 1100 of the semiconductor package 30 may be on the tops of the first and second semiconductor chips 300 and 400, the heat dissipation unit 1100 may emit heat, which is generated by the first and second semiconductor chips 300 and 400, to the outside. Accordingly, the heat dissipation performance of the semiconductor package 30 may be increased.

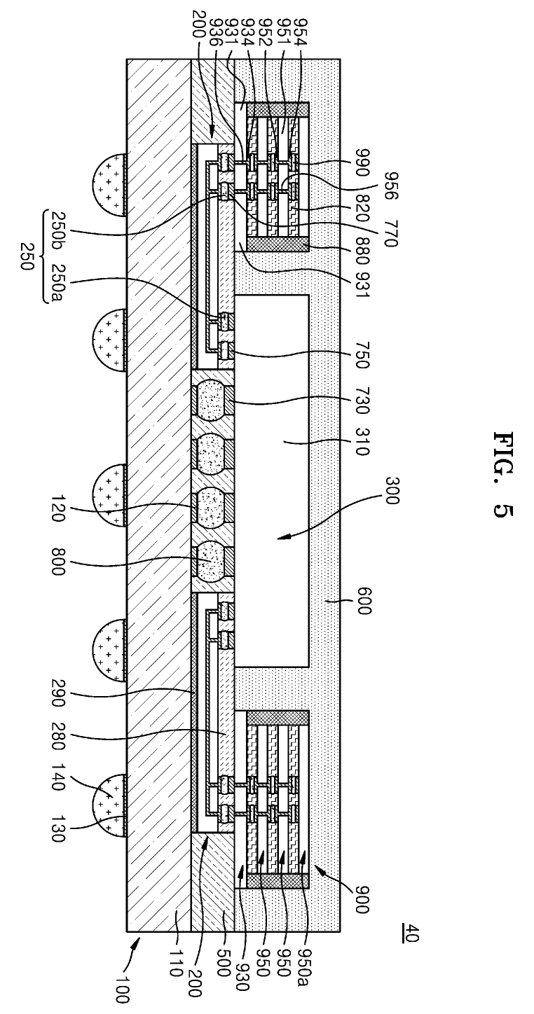

FIG. 5 illustrates a cross-sectional view of a semiconductor package 40 according to embodiments of the inventive concepts. Hereinafter, description of the semiconductor package 40 of FIG. 5 that is redundant with the description of the semiconductor package 10 of FIGS. 1 and 2 is omitted for conciseness, and description hereinafter will be focused on differences between the semiconductor packages 10 and 40.

The semiconductor package 40 may include the package substrate 100, the interposer 200, the first adhesive layer 280, the second adhesive layer 290, the first semiconductor chip 300, a semiconductor stack structure 900, the lower molding layer 500, the upper molding layer 600, the first to third conductive pillars 730, 750, and 770, the chip connection terminal 800, and the interposer connection terminal 250.

The semiconductor stack structure 900 may be mounted on an edge portion of the lower molding layer 500. There may be a plurality of semiconductor stack structures 900. The semiconductor stack structures 900 may be further outside than a side surface of the first semiconductor chip 300 to surround at least a portion of the first semiconductor chip 300.

A semiconductor stack structure 900 may include a second semiconductor chip 930 and a plurality of third semiconductor chips 950 stacked on the second semiconductor chip 930. Although it is illustrated that the semiconductor stack structure 900 includes one second semiconductor chip 930 and three third semiconductor chips 950, embodiments are not limited thereto.

In an example embodiment, the semiconductor stack structure 900 may be referred to as a memory semiconductor stack structure. For example, the semiconductor stack structure 900 may include DRAM, SRAM, flash memory, electrically erasable and programmable read-only memory (EEPROM), PRAM, MRAM, or RRAM.

In an example embodiment, the second semiconductor chip 930 does not include a memory cell, and the third semiconductor chips 950 may include a memory cell. For example, the second semiconductor chip 930 may correspond to a buffer chip including a serial-to-parallel conversion circuit, a test logic circuit such as a design-for-test (DFT) circuit, a Joint Test Action Group (JTAG) circuit, or a memory built-in self-test (MBIST) circuit, or a signal interface circuit such as a PHY.

Each of the third semiconductor chips 950 may correspond to a memory semiconductor chip. For example, when the second semiconductor chip 930 corresponds to a buffer chip controlling HBM DRAM, each third semiconductor chip 950 may correspond to a memory semiconductor chip having an HBM DRAM cell controlled by the second semiconductor chip 930.

In an example embodiment, the second semiconductor chip 930 may include a second semiconductor substrate 931, an upper connection pad 934, and a plurality of through silicon vias 936. The third semiconductor chip 950 may include a third semiconductor substrate 951, a lower connection pad 952, an upper connection pad 954, and a plurality of through silicon vias 956.

An active layer of the second semiconductor substrate 931 may include a plurality of individual devices. The third conductive pillar 770 on the bottom surface of the second semiconductor chip 930 may be electrically connected to a plurality of individual devices in the active layer of the second semiconductor substrate 931. The upper connection pad 934 may be on the top surface of the second semiconductor substrate 931.

The through silicon vias 936 may pass through at least a portion of the second semiconductor substrate 931 in the vertical direction and electrically connect the upper connection pad 934 to the third conductive pillar 770.

An active layer of the third semiconductor substrate 951 may include a plurality of individual devices. The lower connection pad 952 may be on the bottom surface of the third semiconductor substrate 951, which is adjacent to the active layer of the third semiconductor substrate 951. The upper connection pad 954 may be on the top surface of the third semiconductor substrate 951. The through silicon vias 956 may pass through at least a portion of the third semiconductor substrate 951 in the vertical direction and electrically connect the lower connection pad 952 to the upper connection pad 954. The through silicon vias 956 of the third semiconductor chip 950 may be electrically connected to the through silicon vias 936 of the second semiconductor chip 930.

A chip connection terminal 990 may be between the upper connection pad 934 of the second semiconductor chip 930 and the lower connection pad 952 of the third semiconductor chip 950, and may electrically connect the second semiconductor chip 930 to the third semiconductor chip 950.

In addition, a chip connection terminal 990 may be between the lower connection pad 952 of one of two adjacent third semiconductor chips 950 and the upper connection pad 954 of the other of the two adjacent third semiconductor chips 950, and may electrically connect the two adjacent third semiconductor chips 950.

In an example embodiment, the horizontal length of the second semiconductor chip 930 may be greater than the horizontal length of each third semiconductor chip 950. The horizontal cross-sectional area of the second semiconductor chip 930 may be greater than the horizontal cross-sectional area of the third semiconductor chip 950.

In an example embodiment, a third semiconductor chip 950a, which is farthest from the second semiconductor chip 930 in the vertical direction among the plurality of third semiconductor chips 950, may not include the upper connection pad 954 and the through silicon vias 956.

In an example embodiment, an insulating adhesive layer 820 may be between the second semiconductor chip 930 and a third semiconductor chip 950, or between two adjacent third semiconductor chips 950. The insulating adhesive layer 820 may surround the side of the chip connection terminal 990.

In an example embodiment, the insulating adhesive layer 820 may include an NCF, NCP, an insulating polymer, or epoxy resin.

The semiconductor stack structure 900 may further include a molding layer 880, which is on the second semiconductor chip 930 and surrounds the plurality of third semiconductor chips 950. For example, the molding layer 880 may include an epoxy molding compound (EMC).

In an example embodiment, the molding layer 880 may not cover the top surface of the third semiconductor chip 950a. In other words, the top surface of the molding layer 880 may be coplanar with the top surface of the third semiconductor chip 950a. However, embodiments are not limited to the descriptions above. The molding layer 880 may cover the top surface of the third semiconductor chip 950a.

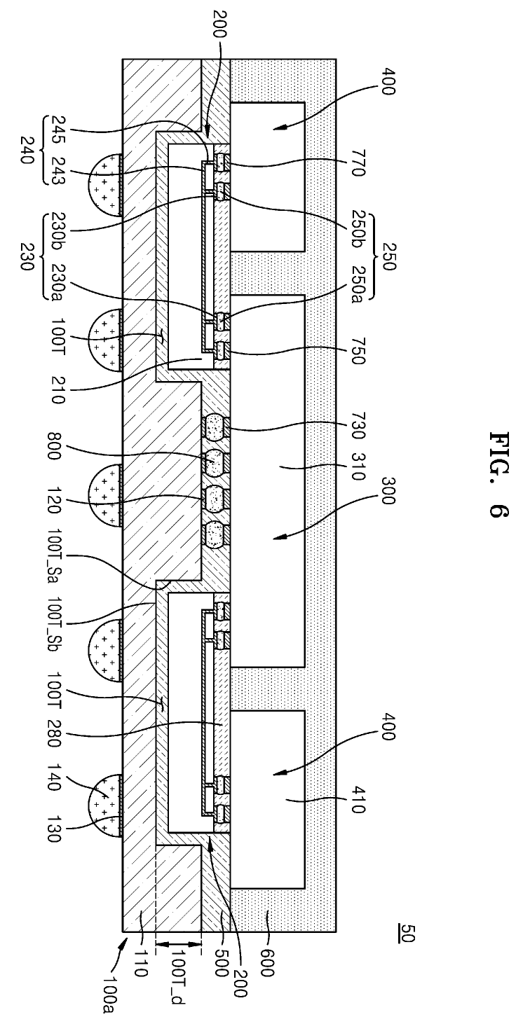

FIG. 6 illustrates a cross-sectional view of a semiconductor package 50 according to embodiments of the inventive concepts.

Hereinafter, description of the semiconductor package 50 of FIG. 6 that is redundant with the description of the semiconductor package 10 of FIGS. 1 and 2 is omitted for conciseness, and description hereinafter will be focused on differences between the semiconductor packages 10 and 50.

According to an example embodiment, the semiconductor package 50 may include a package substrate 100a, the interposer 200, the first adhesive layer 280, the first semiconductor chip 300, the second semiconductor chip 400, the lower molding layer 500, the upper molding layer 600, the first to third conductive pillars 730, 750, and 770, the chip connection terminal 800, and the interposer connection terminal 250.

The package substrate 100a may include a trench 100T surrounding at least a portion of the interposer 200. In an example embodiment, the trench 100T may include a concave groove. For example, according to the top view of the package substrate 100a, the trench 100T may include a quadrangular or circular groove. However, the shape of the trench 100T of the package substrate 100a is not limited to those described above.

The package substrate 100a may include a first inner surface 100T_Sa and a second inner surface 100T_Sb, which define the trench 100T. Among the inner surfaces of the package substrate 100a which define the trench 100T, the first inner surface 100T_Sa may face a side surface of the interposer 200, and the second inner surface 100T_Sb may face the bottom surface of the interposer 200.

The horizontal length of the trench 100T of the package substrate 100a may be greater than the horizontal length of the interposer 200. According to the top view of the semiconductor package 50, the cross-sectional area of the trench 100T of the package substrate 100a may be greater than the cross-sectional area of the interposer 200.

A vertical length 100T_d of the trench 100T of the package substrate 100a may be about 20 micrometers to about 200 micrometers. However, the vertical length 100T_d of the trench 100T of the package substrate 100a is not limited thereto.

There may be a plurality of interposers 200. At least a portion of each of the interposers 200 may be surrounded by the trench 100T of the package substrate 100a. In detail, the first and second inner surfaces 100T_Sa and 100T_Sb defining the trench 100T of the package substrate 100a may surround at least a portion of an interposer 200.

In an example embodiment, the interposer 200 may be separated from the first and second inner surfaces 100T_Sa and 100T_Sb defining the trench 100T of the package substrate 100a. For example, a side surface of the interposer 200 may be separated from the first inner surface 100T_Sa in the horizontal direction, and the bottom surface of the interposer 200 may be separated from the second inner surface 100T_Sb in the vertical direction. In other words, the interposer 200 may not be in contact with the package substrate 100a.

In an example embodiment, the lower molding layer 500 may fill the space between the interposer 200 and the package substrate 100a. For example, a portion of the lower molding layer 500 may be between the side surface of the interposer 200 and the first inner surface 100T_Sa of the package substrate 100a, and another portion of the lower molding layer 500 may be between the bottom surface of the interposer 200 and the second inner surface 100T_Sb of the package substrate 100a.

According to an example embodiment, the semiconductor package 50 may include the package substrate 100a having the trench 100T accommodating at least a portion of the interposer 200, and thus may be thin and light.

In addition, the semiconductor package 50 may include the lower molding layer 500 that fills the space between the interposer 200 and the package substrate 100a, and accordingly, the structural reliability of the semiconductor package 50 may be increased.

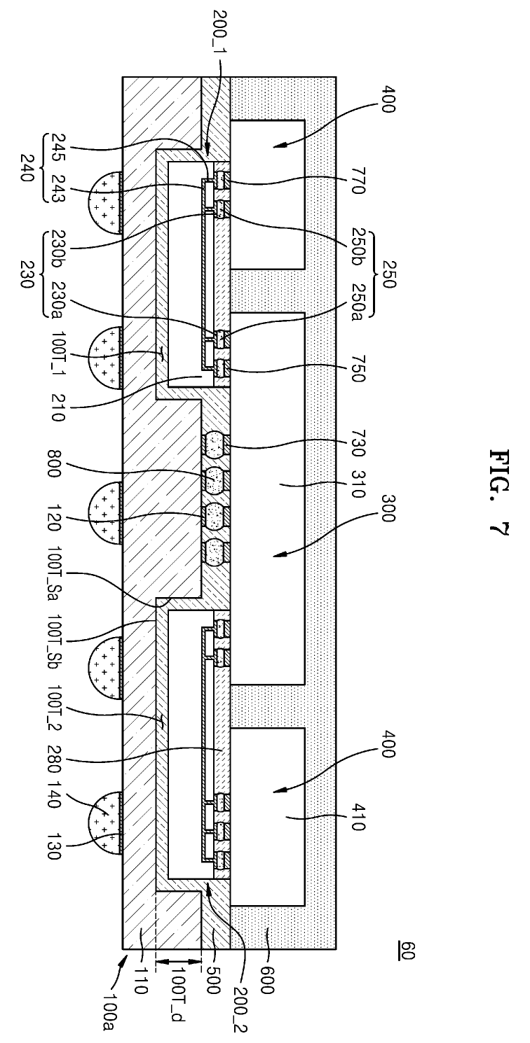

FIG. 7 illustrates a cross-sectional view of a semiconductor package 60 according to embodiments of the inventive concepts.

Hereinafter, description of the semiconductor package 60 of FIG. 7 that is redundant with the description of the semiconductor package 50 of FIG. 6 is omitted for conciseness, and description hereinafter will be focused on differences between the semiconductor packages 50 and 60.

The semiconductor package 60 may include the first interposer 200_1 and the second interposer 200_2. In an example embodiment, each of the first interposer 200_1 and the second interposer 200_2 may include the interposer substrate 210, the interposer upper pad 230, and the interposer wiring pattern 240.

In an example embodiment, the size of the first interposer 200_1 may be different from the size of the second interposer 200_2. For example, the horizontal length of the first interposer 200_1 may be less than the horizontal length of the second interposer 200_2. Although not specifically shown FIG. 7, the vertical length of the first interposer 200_1 may be less than the vertical length of the second interposer 200_2.

In an example embodiment, according to the top view of the semiconductor package 60, the cross-sectional area of the first interposer 200_1 may be less than the cross-sectional area of the second interposer 200_2. According to the top view of the package substrate 100a, the cross-sectional area of a trench 100T_1 of the package substrate 100a which accommodates the first interposer 200_1, may be less than the cross-sectional area of a trench 100T_2 of the package substrate 100a which accommodates the second interposer 200_2.

In an example embodiment, because the vertical length of the first interposer 200_1 is less than the vertical length of the second interposer 200_2, the depth of the trench 100T_1 of the package substrate 100a which accommodates at least a portion of the first interposer 200_1 may be less than the depth of the trench 100T_2 of the package substrate 100a which accommodates at least a portion of the second interposer 200_2.

In other words, because the package substrate 100a may include a plurality of trenches, e.g., the trenches 100T_1 and 100T_2 having different vertical lengths, the semiconductor package 60 may include a plurality of interposers, e.g., the first and second interposers 200_1 and 200_1, having different sizes. In addition, the trenches, e.g., the trenches 100T_1 and 100T_2, of the package substrate 100a may respectively accommodate the interposers, e.g., the first and second interposers 200_1 and 200_1, having different vertical lengths, and accordingly, the vertical length (i.e., thickness) of the semiconductor package 60 may be uniform in the horizontal direction.

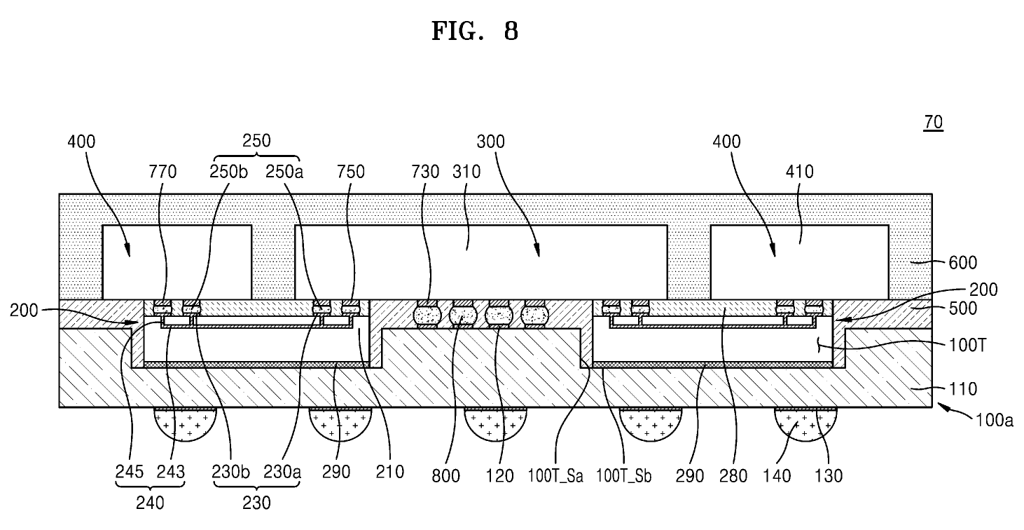

FIG. 8 illustrates a cross-sectional view of a semiconductor package 70 according to embodiments of the inventive concepts.

Hereinafter, description of the semiconductor package 70 of FIG. 8 that is redundant with the description of the semiconductor package 50 of FIG. 6 is omitted for conciseness, and description hereinafter will be focused on differences between the semiconductor packages 50 and 70.

In an example embodiment, at least a portion of each of a plurality of interposers 200 may be surrounded by the trench 100T of the package substrate 100a. In detail, the first and second inner surfaces 100T_Sa and 100T_Sb defining the trench 100T of the package substrate 100a may surround at least a portion of an interposer 200.

In an example embodiment, the bottom of the interposer 200 may be supported by the package substrate 100a. In detail, at least a portion of the interposer 200 may be accommodated in the trench 100T of the package substrate 100a, and the bottom of the interposer 200 may be supported by the second inner surface 100T_Sb defining the trench 100T of the package substrate 100a.

In an example embodiment, a side surface of the interposer 200 may be separated from the first inner surface 100T_Sa of the package substrate 100a in the horizontal direction, and the bottom surface of the interposer 200 may be in contact with the second inner surface 100T_Sb of the package substrate 100a.

In an example embodiment, the lower molding layer 500 may fill the space between the interposer 200 and the package substrate 100a. For example, a portion of the lower molding layer 500 may be between the side surface of the interposer 200 and the first inner surface 100T_Sa of the package substrate 100a.

In an example embodiment, the second adhesive layer 290 may be between the interposer 200 and the package substrate 100a, and may fix the interposer 200 to the second inner surface 100T_Sb of the package substrate 100a. However, embodiments are not limited to the descriptions above. The second adhesive layer 290 may be omitted from the semiconductor package 70.

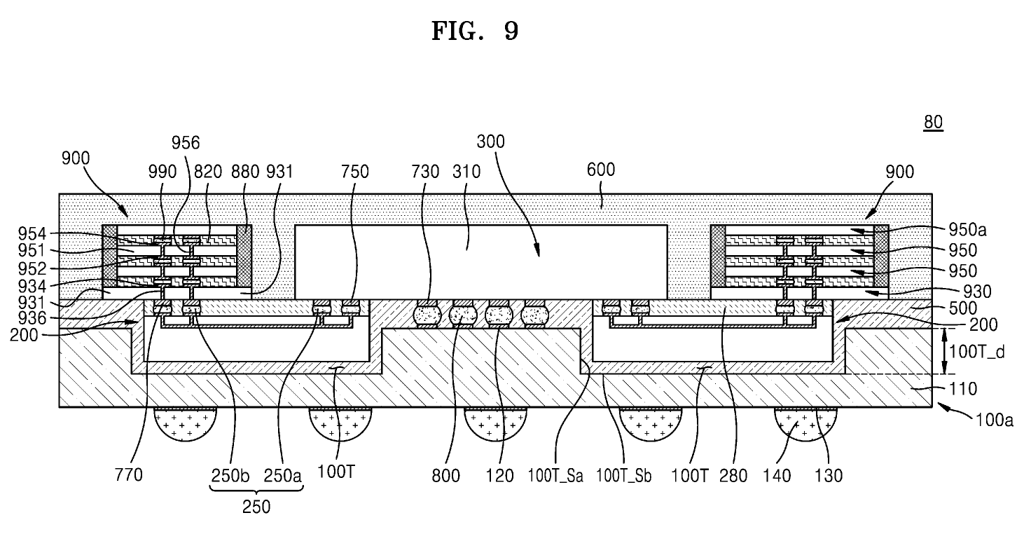

FIG. 9 illustrates a cross-sectional view of a semiconductor package 80 according to embodiments of the inventive concepts.

Hereinafter, description of the semiconductor package 80 of FIG. 9 that is redundant with the description of the semiconductor package 50 of FIG. 6 is omitted for conciseness, and description hereinafter will be focused on differences between the semiconductor packages 50 and 80.

The semiconductor package 80 may include the package substrate 100a, the interposer 200, the first adhesive layer 280, the first semiconductor chip 300, the semiconductor stack structure 900, the lower molding layer 500, the upper molding layer 600, the first to third conductive pillars 730, 750, and 770, the chip connection terminal 800, and the interposer connection terminal 250.

The semiconductor stack structure 900 may be mounted on an edge portion of the lower molding layer 500. There may be a plurality of semiconductor stack structures 900. The semiconductor stack structures 900 may be further outside than a side surface of the first semiconductor chip 300 to surround at least a portion of the first semiconductor chip 300.

A semiconductor stack structure 900 may include the second semiconductor chip 930 and a plurality of third semiconductor chips 950 stacked on the second semiconductor chip 930.

In an example embodiment, the second semiconductor chip 930 may include the second semiconductor substrate 931, the upper connection pad 934, and a plurality of through silicon vias 936. A third semiconductor chip 950 may include the third semiconductor substrate 951, the lower connection pad 952, the upper connection pad 954, and a plurality of through silicon vias 956.

A chip connection terminal 990 may be between the upper connection pad 934 of the second semiconductor chip 930 and the lower connection pad 952 of the third semiconductor chip 950, and may electrically connect the second semiconductor chip 930 to the third semiconductor chip 950. In addition, the chip connection terminal 990 may be between the lower connection pad 952 of one of two adjacent third semiconductor chips 950 and the upper connection pad 934 of the other of the two adjacent third semiconductor chips 950, and may electrically connect the two adjacent third semiconductor chips 950.

The insulating adhesive layer 820 may be between the second semiconductor chip 930 and a third semiconductor chip 950, or between two adjacent third semiconductor chips 950. The insulating adhesive layer 820 may surround the side of the chip connection terminal 990.

The molding layer 880 may be on the second semiconductor chip 930 and surround the plurality of third semiconductor chips 950. In addition, the molding layer 880 may not cover the top surface of the third semiconductor chip 950a.

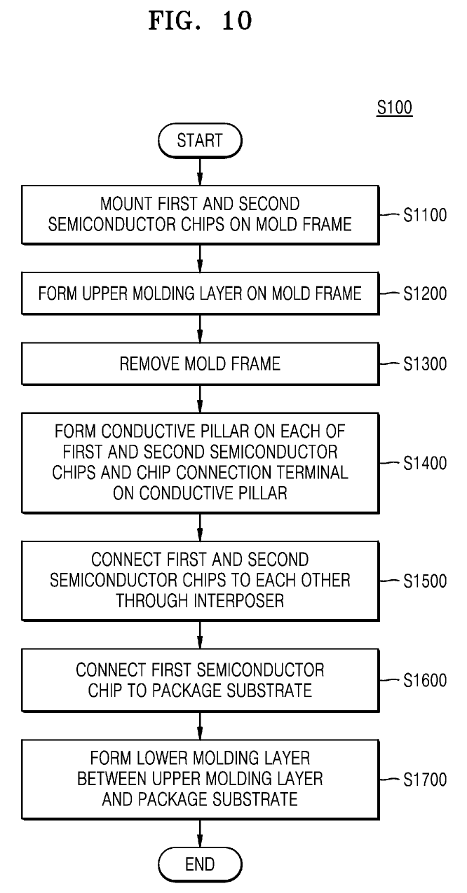

Hereinafter, a method S100 of manufacturing a semiconductor package is described in detail with reference to FIGS. 10 to 16. The method S100 according to an example embodiment may correspond to a method of manufacturing the semiconductor package 50 of FIG. 6.

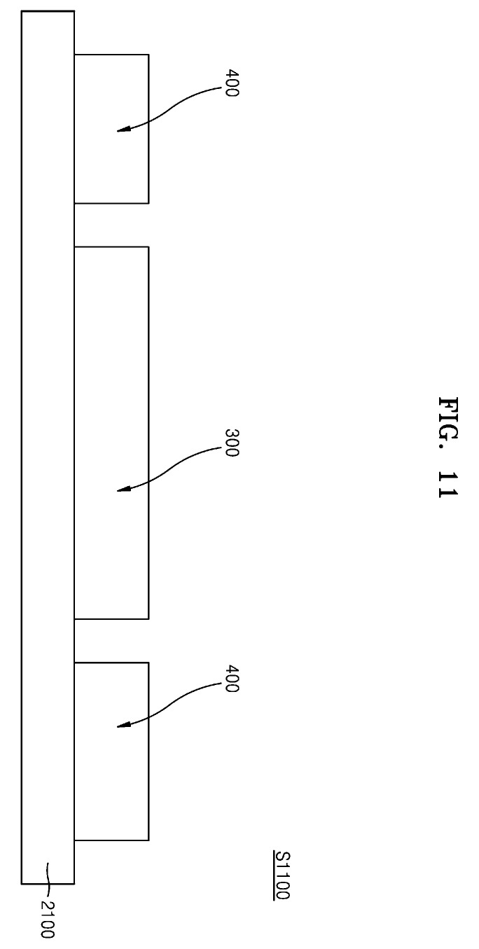

FIG. 10 illustrates a flowchart of the method S100 of manufacturing the semiconductor package 50, according to embodiments of the inventive concepts. FIGS. 11 to 17 illustrate diagrams of stages in the method S100 of manufacturing the semiconductor package 50, according to an example embodiment.

In an example embodiment, the method S100 of manufacturing the semiconductor package 50 may be performed at a wafer level.

Referring to FIG. 10, the method S100 of manufacturing the semiconductor package 50 may include mounting the first semiconductor chip 300 and the second semiconductor chip 400 on a mold frame 2100 in operation S1100, forming the upper molding layer 600 on the mold frame 2100 in operation S1200, removing the mold frame 2100 in operation S1300, forming the first to third conductive pillars 730, 750, and 770 and the chip connection terminal 800 on the first and second semiconductor chips 300 and 400 in operation S1400, connecting the first semiconductor chip 300 to the second semiconductor chip 400 through the interposer 200 in operation S1500, connecting the first semiconductor chip 300 to the package substrate 100a in operation S1600, and forming the lower molding layer 500 between the upper molding layer 600 and the package substrate 100a in operation S1700.

Referring to FIGS. 10 and 11, the method S100 of manufacturing the semiconductor package 50 includes mounting the first semiconductor chip 300 and the second semiconductor chip 400 on the mold frame 2100 in operation S1100.

In an example embodiment, the mold frame 2100 may include a material that has stability with respect to semiconductor processes such as a coating process, a baking process, or an etching process.

In the case where the mold frame 2100 is separated and removed by laser ablation afterward, the mold frame 2100 may include a transparent substrate. Optionally, in the case where the mold frame 2100 is separated and removed by heating, the mold frame 2100 may include a heat resistant substrate.

In example embodiments, the mold frame 2100 may include a glass substrate. In an example embodiment, the mold frame 2100 may include heat resistant organic polymer material, such as polyimide (PI), polyetheretherketone (PEEK), polyethersulfone (PES), or polyphenylene sulfide (PPS), but is not limited thereto.

A release film may be attached to a surface of the mold frame 2100. For example, the release film may include a laser reactive layer that reacts to laser radiation and evaporates such that the mold frame 2100 is separable. The release film may include a carbon-based material layer. For example, the release film may include an amorphous carbon layer (ACL).

In operation S1100, the first semiconductor chip 300 and the second semiconductor chip 400 may be mounted on the mold frame 2100 such that an active layer of each of the first and second semiconductor chips 300 and 400 faces the mold frame 2100.

In an example embodiment, the first semiconductor chip 300 may be mounted on a central portion of the mold frame 2100 in operation S1100. After the first semiconductor chip 300 is mounted on the mold frame 2100, a plurality of second semiconductor chips 400 may be mounted on the mold frame 2100 to surround the sides of the first semiconductor chip 300.

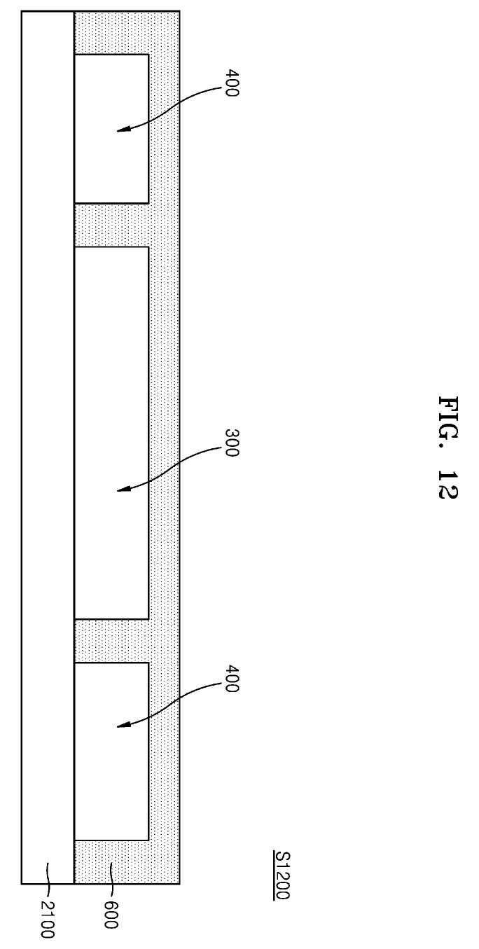

Referring to FIGS. 10 and 12, the method S100 of manufacturing the semiconductor package 50 includes forming the upper molding layer 600 on the mold frame 2100 in operation S1200.

In operation S1200, the upper molding layer 600 may be on the mold frame 2100 and surround the first and second semiconductor chips 300 and 400. In an example embodiment, the upper molding layer 600 may surround the sides and tops of the first and second semiconductor chips 300 and 400.

In an example embodiment, the upper molding layer 600 may be partially ground in operation S1200. For example, although not shown in FIG. 12, the upper molding layer 600 may be partially removed such that the top surface of the upper molding layer 600 is coplanar with the top surfaces of the first and second semiconductor chips 300 and 400.

When the top surface of the upper molding layer 600 is coplanar with the top surfaces of the first and second semiconductor chips 300 and 400, the semiconductor package 50 manufactured using the method S100 may be thin and light. In addition, the top surfaces of the first and second semiconductor chips 300 and 400 may be exposed, and accordingly, the heat dissipation performance of the semiconductor package 50 including the first and second semiconductor chips 300 and 400 may be increased.

In an example embodiment, after the upper molding layer 600 is at least partially removed, the heat dissipation unit 1100 (in FIG. 4) may be mounted on the first and second semiconductor chips 300 and 400 and the upper molding layer 600.

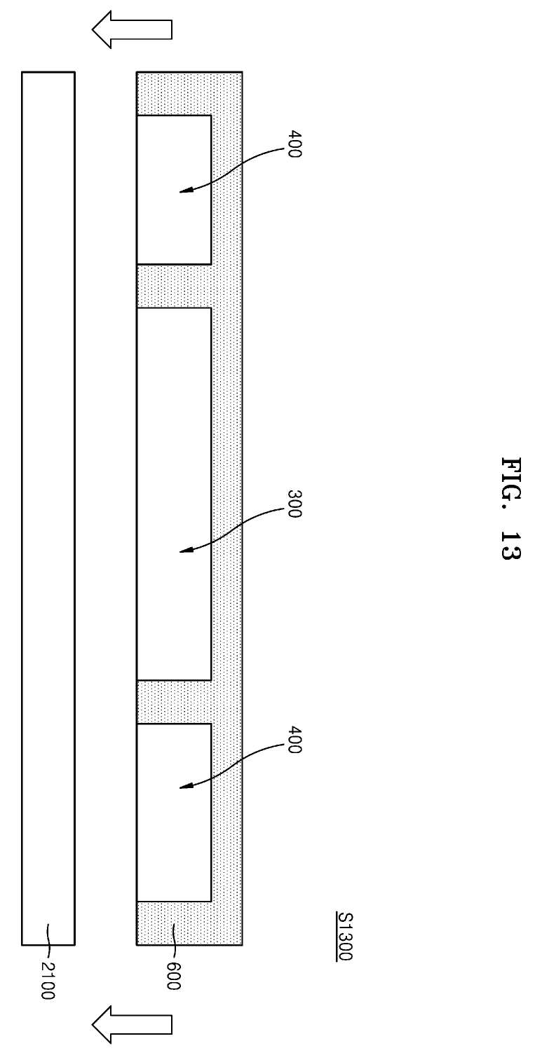

Referring to FIGS. 10 and 13, the method S100 of manufacturing the semiconductor package 50 includes removing the mold frame 2100 in operation S1300.

In an example embodiment, the mold frame 2100 may be separated and removed by laser ablation in operation S1300. However, embodiments are not limited thereto. The mold frame 2100 may be separated and removed by heating or laser radiation.

In an example embodiment, after operation S1300, individual devices and micropatterns inside the active layer of each of the first and second semiconductor chips 300 and 400 may be exposed.

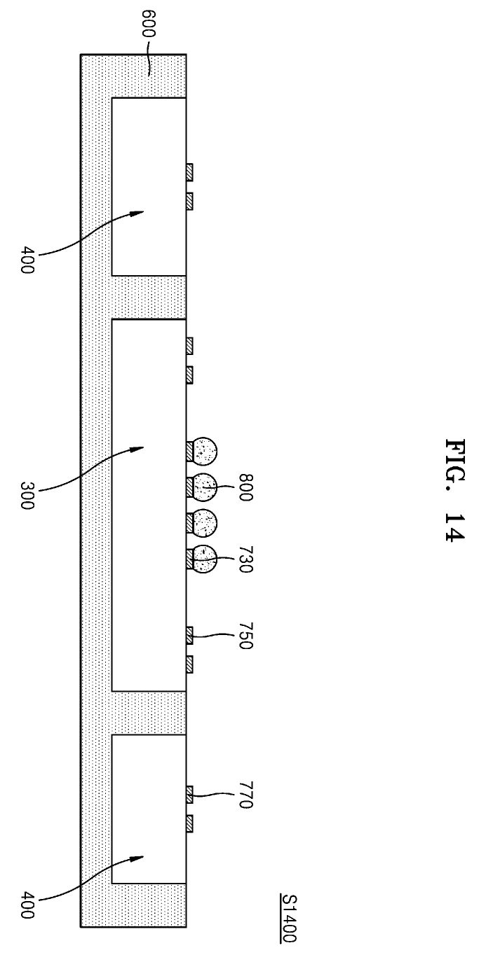

Referring to FIGS. 10 and 14, the method S100 of manufacturing the semiconductor package 50 includes forming the first to third conductive pillars 730, 750, and 770 and the chip connection terminal 800 on the first and second semiconductor chips 300 and 400 in operation S1400.

In operation S1400, the first conductive pillar(s) 730 may be arranged in the central portion of the first semiconductor chip 300. In detail, the first conductive pillar 730 may be arranged in the central portion of the first semiconductor chip 300 and electrically connected to individual devices inside the active layer of the first semiconductor chip 300.

In addition, the second conductive pillar(s) 750 may be arranged in the edge portion of the first semiconductor chip 300 to be at an outer side of the first conductive pillar 730 in operation S1400. In detail, the second conductive pillar 750 may be arranged in the edge portion of the first semiconductor chip 300 and electrically connected to individual devices inside the active layer of the first semiconductor chip 300.

In addition, the third conductive pillar(s) 770 may be arranged on the second semiconductor chip 400 in operation S1400. In detail, the third conductive pillar 770 may be arranged on the second semiconductor chip 400 and electrically connected to individual devices inside the active layer of the second semiconductor chip 400.

In operation S1400, the chip connection terminal 800 may be mounted on the first conductive pillar 730. In an example embodiment, the vertical length 800d of the chip connection terminal 800 mounted on the first conductive pillar 730 (see FIG. 2) may be about 30 micrometers to about 300 micrometers.

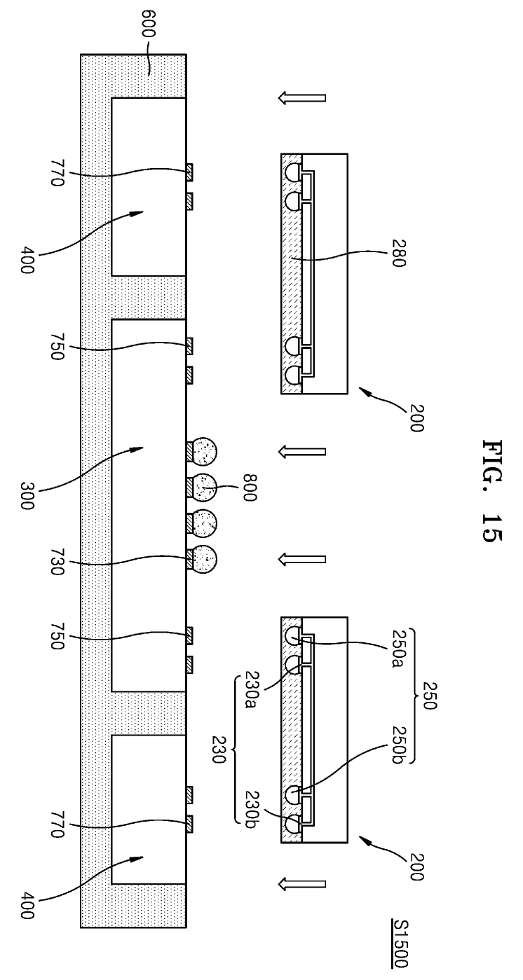

Referring to FIGS. 10 and 15, the method S100 of manufacturing the semiconductor package 50 includes connecting the first semiconductor chip 300 to the second semiconductor chip 400 through the interposer 200 in operation S1500.

In operation S1500, the interposer(s) 200 may be mounted on the first and second semiconductor chips 300 and 400 and may electrically connect the first and second semiconductor chips 300 and 400 to each other through the interposer wiring pattern 240.

Before operation S1500, the first adhesive layer 280 may be attached to the bottom of the interposer 200. For example, the first adhesive layer 280 may include an NCF, NCP, an insulating polymer, or epoxy resin. The first adhesive layer 280 may surround the first and second interposer connection terminals 250a and 250b respectively attached to the first and second interposer upper pads 230a and 230b of the interposer 200.

In an example embodiment, in operation S1500, the interposer 200 may be mounted on the first and second semiconductor chips 300 and 400 such that the interposer 200 overlaps at least a portion of the first semiconductor chip 300 and at least a portion of the second semiconductor chip 400 in the vertical direction. In addition, the interposer 200 may be mounted on the first and second semiconductor chips 300 and 400 such that the interposer 200 does not overlap the first conductive pillar 730 and the chip connection terminal 800 in the vertical direction.

In an example embodiment, the interposer 200 may be electrically connected to the first semiconductor chip 300 through the first interposer connection terminal 250a in operation S1500. In detail, the first interposer connection terminal 250a may be arranged between the second conductive pillar 750 on the first semiconductor chip 300 and the first interposer upper pad 230a of the interposer 200, and may electrically connect the interposer 200 to the first semiconductor chip 300.

In addition, the interposer 200 may be electrically connected to the second semiconductor chip 400 through the second interposer connection terminal 250b in operation S1500. In detail, the second interposer connection terminal 250b may be arranged between the third conductive pillar 770 on the second semiconductor chip 400 and the second interposer upper pad 230b of the interposer 200, and may electrically connect the interposer 200 to the second semiconductor chip 400.

In an example embodiment, the first adhesive layer 280 attached to the bottom of the interposer 200 may surround the second conductive pillar 750 on the first semiconductor chip 300 and the third conductive pillar 770 on the second semiconductor chip 400 in operation S1500.

After operation S1500, the electrical connection between the interposer 200 and the first and second semiconductor chips 300 and 400 may be tested. For example, when the electrical connection between the interposer 200 and the first and second semiconductor chips 300 and 400 is poor, the interposer 200 may be replaced. However, embodiments are not limited thereto. The test for the electrical connection between the interposer 200 and the first and second semiconductor chips 300 and 400 may be skipped.

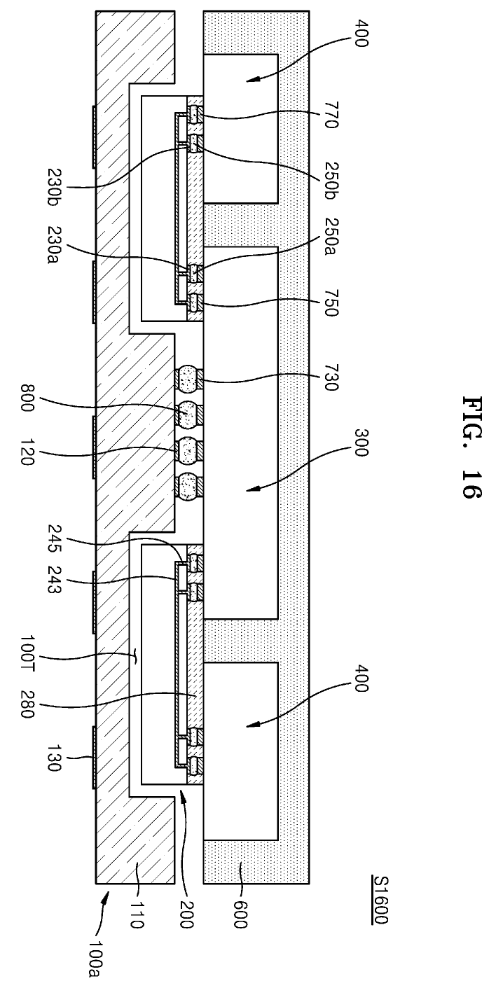

Referring to FIGS. 10 and 16, the method S100 of manufacturing the semiconductor package 50 includes connecting the first semiconductor chip 300 to the package substrate 100a in operation S1600.

In an example embodiment, the chip connection terminal 800 attached to the first conductive pillar 730 may be connected to the upper package substrate pad 120 of the package substrate 100a in operation S1600. Accordingly, the first semiconductor chip 300 may be electrically connected to the package substrate 100a through the first conductive pillar 730, the chip connection terminal 800, and the upper package substrate pad 120.

In an example embodiment, the trench 100T of the package substrate 100a may accommodate at least a portion of the interposer 200 in operation S1600. Accordingly, at least the portion of the interposer 200 may be surrounded by the first and second inner surfaces 100T_Sa and 100T_Sb defining the trench 100T or the package substrate 100a (see FIG. 6).

Detailed description of the trench 100T and the package substrate 100a has been provided with reference to FIGS. 6 to 9, and thus redundant descriptions thereof is here omitted for conciseness.

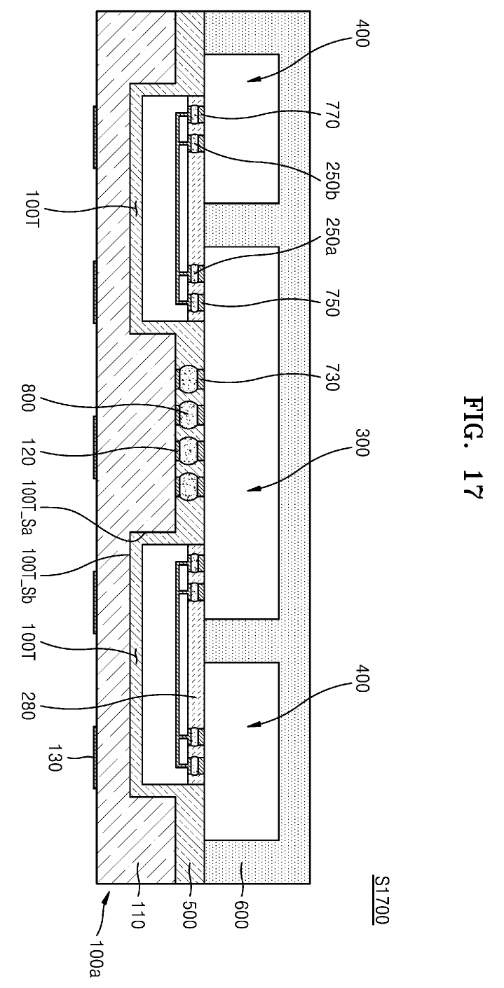

Referring to FIGS. 10 and 17, the method S100 of manufacturing the semiconductor package 50 includes forming the lower molding layer 500 between the upper molding layer 600 and the package substrate 100a in operation S1700.

The lower molding layer 500 may fill the space between the upper molding layer 600 and the package substrate 100a in operation S1700.

In an example embodiment, the lower molding layer 500 may fill the space between the side surface of the interposer 200 and the first inner surface 100T_Sa defining the trench 100T of the package substrate 100a, and the space between the bottom surface of the interposer 200 and the second inner surface 100T_Sb defining the trench 100T of the package substrate 100a.

In addition, the lower molding layer 500 may fill the vertical space between the first semiconductor chip 300 and the top surface of the package substrate 100a and surround the first conductive pillar 730 and the chip connection terminal 800.

According to an example embodiment, the interposer 200 used in the method S100 of manufacturing the semiconductor package 50 does not include a through silicon via that passes through at least a portion of the interposer substrate 210 and that directly connects the first and second semiconductor chips 300 and 400 to the package substrate 100a.

Accordingly, the interposer 200 may be thin and light, and the semiconductor package 50 manufactured using the method S100 may also be thin and light. In addition, because the interposer 200 does not include a through silicon via, the manufacturing cost of the semiconductor package 50 may be reduced.

According to an example embodiment, the method S100 of manufacturing the semiconductor package 50 provides for each of the first and second semiconductor chips 300 and 400 to be accommodated in the trench 100T of the package substrate 100a. Therefore, the semiconductor package 50 manufactured using the method S100 may be thin and light.

According to an example embodiment, the method S100 of manufacturing the semiconductor package 50 may include injecting the lower molding layer 500 into the space between the package substrate 100a and the interposer 200, and the space between the package substrate 100a and the upper molding layer 600. Therefore, the structural reliability of the semiconductor package 50 manufactured using the method S100 may be increased.

While the inventive concepts have been particularly shown and described with reference to embodiments thereof, it should be understood that various changes in form and detail may be made therein without departing from the spirit and scope of the following claims.

What is claimed is:

1. A method of manufacturing a semiconductor package, the method comprising:
mounting a first semiconductor chip and a second semiconductor chip on a mold frame, the second semiconductor chip being at an outer side of the first semiconductor chip;
forming an upper molding layer on the mold frame, the upper molding layer surrounding the first semiconductor chip and the second semiconductor chip;
removing the mold frame;
forming a first conductive pillar on a bottom surface of the first semiconductor chip, forming a second conductive pillar at an outer side of the first conductive pillar, forming a third conductive pillar on a bottom surface of the second semiconductor chip, and mounting a chip connection terminal on the first conductive pillar;
electrically connecting the first semiconductor chip and the second semiconductor chip through an interposer;
electrically connecting the first semiconductor chip to a package substrate by connecting the chip connection terminal to an upper package substrate pad of the package substrate; and
forming a lower molding layer between the upper molding layer and the package substrate, the lower molding layer surrounding the interposer, the first conductive pillar, and the chip connection terminal.

2. The method of claim 1, wherein the electrically connecting the first semiconductor chip and the second semiconductor chip through the interposer comprises arranging a first interposer connection terminal between the interposer and the second conductive pillar, and arranging a second interposer connection terminal between the interposer and the third conductive pillar.

3. The method of claim 1, further comprising, after the forming of the upper molding layer, grinding a portion of the upper molding layer such that a top surface of the upper molding layer is coplanar with a top surface of the first semiconductor chip and a top surface of the second semiconductor chip.

4. The method of claim 3, further comprising, after the grinding of the portion of the upper molding layer, mounting a heat dissipation unit on the top surface of the first semiconductor chip, the top surface of the second semiconductor chip, and the top surface of the upper molding layer.

5. The method of claim 1, wherein the mounting of the first semiconductor chip and the second semiconductor chip is performed such that an active layer of the first semiconductor chip and an active layer of the second semiconductor chip each face the mold frame.

6. The method of claim 1, wherein a vertical length of the first conductive pillar is greater than a vertical length of the second conductive pillar and a vertical length of the third conductive pillar.

7. The method of claim 1, wherein a vertical length of each of the first conductive pillar, the second conductive pillar, and the third conductive pillar is about 10 micrometers to about 150 micrometers.

8. The method of claim 2, wherein a vertical length of the chip connection terminal is greater than a vertical length of the interposer and a vertical length of each of the first interposer connection terminal and the second interposer connection terminal.

9. The method of claim 1, wherein a vertical length of the chip connection terminal is about 30 micrometers to about 300 micrometers.

10. The method of claim 2, further comprising, before the electrically connecting the first semiconductor chip and the second semiconductor chip through the interposer, attaching a first adhesive layer to a bottom surface of the interposer, the first adhesive layer surrounding the first interposer connection terminal and the second interposer connection terminal.

11. A method of manufacturing a semiconductor package, the method comprising:
mounting a first semiconductor chip and a second semiconductor chip on a mold frame, the second semiconductor chip being at an outer side of the first semiconductor chip;
forming an upper molding layer on the mold frame, the upper molding layer surrounding the first semiconductor chip and the second semiconductor chip;
removing the mold frame;
forming conductive pillars on a bottom surface of the first semiconductor chip and a bottom surface of the second semiconductor chip, and mounting a chip connection terminal on one of the conductive pillars;
electrically connecting the first semiconductor chip and the second semiconductor chip using an interposer having a first adhesive layer attached to a bottom surface thereof;
preparing a package substrate having a trench in an upper portion thereof, and connecting the chip connection terminal to an upper package substrate pad of the package substrate such that at least a portion of the interposer is accommodated in the trench; and
forming a lower molding layer filling a space between the upper molding layer and the package substrate and a space between the interposer and inner surfaces of the package substrate defining the trench.

12. The method of claim 11, wherein, in the connecting of the chip connection terminal to the upper package substrate pad of the package substrate, the interposer is separated from the inner surfaces of the package substrate defining the trench.

13. The method of claim 11, wherein, in the connecting of the chip connection terminal to the upper package substrate pad of the package substrate, a bottom surface of the interposer is supported by one of the inner surfaces of the package substrate defining the trench, the one of the inner surfaces facing the bottom surface of the interposer.

14. The method of claim 11, wherein a horizontal cross-sectional area of the trench is greater than a horizontal cross-sectional area of the interposer.

15. The method of claim 11, wherein the preparing of the package substrate comprises forming a first trench and a second trench in the upper portion of the package substrate, the first trench and the second trench having different depths,
the interposer comprises a first interposer at least partially accommodated in the first trench and a second interposer at least partially accommodated in the second trench, and
a vertical length of the first interposer is different from a vertical length of the second interposer.

16. The method of claim 11, further comprising, after the electrically connecting the first semiconductor chip and the second semiconductor chip and before the connecting of the chip connection terminal to the package substrate:
testing an electrical connection between the interposer and the first semiconductor chip and the second semiconductor chip; and
replacing the interposer when the electrical connection is poor as a result of the testing.

17. A method of manufacturing a semiconductor package, the method comprising:
mounting a first semiconductor chip and a semiconductor stack structure on a mold frame, the semiconductor stack structure being at an outer side of the first semiconductor chip and including a plurality of semiconductor chips;
forming an upper molding layer on the mold frame, the upper molding layer surrounding the first semiconductor chip and the semiconductor stack structure;
removing the mold frame;
forming a first conductive pillar on a bottom surface of the first semiconductor chip, forming a second conductive pillar at an outer side of the first conductive pillar, forming a third conductive pillar on a bottom surface of the semiconductor stack structure, and mounting a chip connection terminal on the first conductive pillar;
electrically connecting the first semiconductor chip and the semiconductor stack structure using an interposer having a first adhesive layer attached to a bottom surface thereof, by arranging a first interposer connection terminal between the second conductive pillar and the interposer and arranging a second interposer connection terminal between the third conductive pillar and the interposer;
connecting the chip connection terminal to a package substrate; and
forming a lower molding layer between the upper molding layer and the package substrate, the lower molding layer surrounding the interposer,
wherein the semiconductor stack structure comprises a second semiconductor chip and a plurality of third semiconductor chips stacked on the second semiconductor chip.

18. The method of claim 17, wherein the second semiconductor chip is a buffer chip configured to control the plurality of third semiconductor chips, and each of the plurality of third semiconductor chips is a memory semiconductor chip comprising a memory cell.

19. The method of claim 17, wherein the package substrate comprises a trench in an upper portion thereof, and in the connecting of the chip connection terminal to the package substrate, at least a portion of the interposer is accommodated in the trench.

20. The method of claim 17, wherein the semiconductor stack structure further comprises:
an upper connection pad on a top surface of the second semiconductor chip; and
a plurality of through silicon vias passing through at least a portion of the second semiconductor chip in a vertical direction and electrically connecting the third conductive pillar to the upper connection pad.
